(19) United States
(12) Patent Application Publication
(10) Pub. No.: US 2026/0164886 A1
(43) Pub. Date: Jun. 11, 2026

(54) Light Emitting Diode, Display Device Including Light Emitting Diode and Method of Fabricating the Same

(71) Applicant: LG Display Co., Ltd., Seoul (KR)

(72) Inventors: Sang-Hoon LEE, Paju-si (KR); Ju-Sang RHIM, Paju-si (KR); Hyeong-Seok KIM, Paju-si (KR)

(21) Appl. No.: 19/207,894

(22) Filed: May 14, 2025

(30) Foreign Application Priority Data
Dec. 9, 2024 (KR) 10-2024-0181842

(51) Int. Cl. H10H 29/49; H10H 29/01; H10H 29/41

(52) U.S. Cl. CPC H10H 29/49; H10H 29/012; H10H 29/41

(57) ABSTRACT

A light emitting diode includes: a first semiconductor layer; an active layer on a first portion of the first semiconductor layer; a second semiconductor layer on the active layer; a first electrode on a second portion of the first semiconductor layer that is spaced apart from the first portion; a second electrode on the second semiconductor layer; a first chip insulating layer on the first electrode and the second electrode; a first test electrode and a second test electrode on the first chip insulating layer, the first test electrode connected to the first electrode and the second test electrode connected to the second electrode; and a second chip insulating layer on the first test electrode and the second test electrode.

### CROSS-REFERENCE TO RELATED APPLICATION

The present application claims the priority of Republic of Korea Patent Application No. 10-2024-0181842 filed on Dec. 9, 2024, which is hereby incorporated by reference in its entirety.

### BACKGROUND

### Field of the Disclosure

The present disclosure relates to a display device, and more particularly, to a display device including a light emitting diode capable of performing a lighting test and a method of fabricating the display device.

### Description of the Background

Recently, various flat panel display devices such as a liquid crystal display device (LCD), an organic light emitting diode (OLED) display device, and a field emission display (FED) device having excellent properties of a thin profile, a light weight and a low power consumption have been developed and applied to various fields.

Although the OLED display device among the various flat panel display devices has an advantage such that an additional light source is not required, the OLED display device has a disadvantage such that deterioration may occur by an external circumstance due to a property of an organic material vulnerable to moisture and oxygen.

To overcome the disadvantage, a display device using a light emitting diode chip (or a light emitting diode) of an inorganic material has been suggested.

The light emitting diode chip is attached to a display panel after the light emitting diode chip is formed on a growth substrate. Although an optical property such as a wavelength is judged through a photoluminescence (PL) test for the light emitting diode of the growth substrate, a lighting test for judging a normal operation or an abnormal operation may be performed after the light emitting diode is attached to a display panel.

As a result, a production yield is reduced by attaching the light emitting diode of an abnormal operation to the display panel, and a fabrication cost of the display device increases due to a rework of the light emitting diode of an abnormal operation.

### SUMMARY

Accordingly, the present disclosure is directed to a display device that substantially obviates one or more of the problems due to limitations and disadvantages of the related art.

More specifically, the present disclosure is to provide a display device where deterioration is reduced, a production yield increases, and a fabrication process is optimized by forming a test electrode on a light emitting diode of a growth substrate and performing a lighting test and a method of fabricating the display device.

Further, the present disclosure is to provide a display device where a fabrication cost is reduced by forming a test electrode on a light emitting diode of a growth substrate and attaching the light emitting diode of a normal operation to a display panel after a lighting test.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a light emitting diode includes: first semiconductor layer; an active layer on a first portion of the first semiconductor layer; a second semiconductor layer on the active layer; a first electrode on a second portion of the first semiconductor layer that is spaced apart from the first portion of the first semiconductor layer; a second electrode on the second semiconductor layer; a first chip insulating layer on the first electrode and the second electrode; a first test electrode and a second test electrode on the first chip insulating layer, the first test electrode connected to the first electrode and the second test electrode connected to the second electrode; and a second chip insulating layer on the first test electrode and the second test electrode.

In one embodiment, a display device comprises: a gate line and a data line; a transistor connected to the gate line and the data line; a planarizing layer on the transistor; a connecting electrode on the planarizing layer, the connecting electrode connected to the transistor; an adhesive layer on the connecting electrode; a light emitting diode on the adhesive layer; and a first connecting line on the adhesive layer, the first connecting line on a side surface of the light emitting diode at a first side of the light emitting diode; and a second connecting line on the adhesive layer, the second connecting line connected to the connecting electrode and on the side surface of the light emitting diode at a second side of the light emitting diode.

In one embodiment, a method of fabricating a light emitting diode, comprising: sequentially forming an etch stopping layer, a first semiconductor layer, an active layer and a second semiconductor layer on a growth substrate; forming a first electrode on the first semiconductor layer and a second electrode on the second semiconductor layer; forming a first test electrode on the first electrode such that the first test electrode is connected to the first electrode and a second test electrode on the second electrode such that the second test electrode is connected to the second electrode; forming a sacrificing layer on the first test electrode and the second test electrode; attaching a transfer substrate on the sacrificing layer; removing the growth substrate from the etch stopping layer; performing a lighting test by applying a high level signal to the first test electrode and a low level signal to the second test electrode; removing the etch stopping layer from the first semiconductor layer; and detaching a light emitting diode including the first semiconductor layer, the active layer, the second semiconductor layer, the first electrode, and the second electrode from the transfer substrate by removing the sacrificing layer.

In one embodiment, a display device comprises: a substrate; a transistor on the substrate; a first planarizing layer on the transistor; and a light-emitting element that is electrically connected to the transistor, the light-emitting element comprising: a first semiconductor layer; an active layer on a first portion of the first semiconductor layer; a second semiconductor layer on the active layer; a first electrode on a second portion of the first semiconductor layer that is spaced apart from the first portion of the first semiconductor layer; a second electrode on the second semiconductor layer; a first chip insulating layer on the first electrode and the second electrode; a first test electrode and a second test electrode on the first chip insulating layer, the first test electrode connected to the first electrode and the second test electrode connected to the second electrode; and a second chip insulating layer on the first test electrode and the second test electrode, wherein an end of the first test electrode, an end of the second test electrode, at least one end of the first chip insulating layer, and a bottom surface of the first semiconductor layer are planar with each other.

It is to be understood that both the foregoing general description and the following detailed description are explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure.

In the drawings:

FIG. 1 is a view showing a display device according to a first embodiment of the present disclosure;

FIG. 2 is a circuit diagram showing a subpixel of a display device according to a first embodiment of the present disclosure;

FIG. 3 is a cross-sectional view showing a subpixel of a display panel of a display device according to a first embodiment of the present disclosure;

FIG. 4 is a view showing a light emitting diode attached to a display device according to a first embodiment of the present disclosure;

FIGS. 5A to 5E are views showing a method of fabricating a light emitting diode attached to a display device according to a first embodiment of the present disclosure; and

FIG. 6 is a cross-sectional view showing a subpixel of a display panel of a display device according to a second embodiment of the present disclosure.

### DETAILED DESCRIPTION

Advantages and features of the present disclosure, and implementation methods thereof will be clarified through following example aspects described with reference to the accompanying drawings. The present disclosure may, however, be embodied in different forms and should not be construed as limited to the example aspects set forth herein. Rather, these example aspects are provided so that this disclosure may be sufficiently thorough and complete to assist those skilled in the art to fully understand the scope of the present disclosure. Further, the present disclosure is only defined by scopes of claims.

The shapes, sizes, ratios, angles, numbers, and the like, which are illustrated in the drawings to describe various example aspects of the present disclosure, are merely given by way of example. Therefore, the present disclosure is not limited to the illustrations in the drawings. Like reference numerals refer to like elements throughout the specification, unless otherwise specified.

In the following description, where the detailed description of the relevant known function or configuration may unnecessarily obscure a feature or aspect of the present disclosure, a detailed description of such known function or configuration may be omitted or a brief description may be provided.

Where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween.

Although the terms “first,” “second,” A, B, (a), (b), and the like may be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the present disclosure.

The term “at least one” should be understood to include all combinations of one or more of related elements. For example, the term of “at least one of first, second and third elements” may include all combinations of two or more of the first, second and third elements as well as the first, second or third element.

The term “display device” may include a display device in a narrow sense such as liquid crystal module (LCM), an organic light emitting diode (OLED) module and a quantum dot (QD) module including a display panel and a driving unit for driving the display panel. In addition, the term “display device” may include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure may include an applied product or a set device of a final user's device including the LCM, the OLED module and the QD module as well as a display device in a narrow sense such as the LCM, the OLED module and the QD module.

According to circumstances, the LCM, the OLED module, and the QD module having a display panel and a driving unit may be expressed as “a display device”, and an electronic apparatus of a complete product including the LCM, the OLED module and the QD module may be expressed as “a set device.” For example, a display device in a narrow sense may include a display panel of a liquid crystal, an organic light emitting diode and a quantum dot and a source printed circuit board (PCB) of a control unit for driving the display panel, and a set device may further include a set PCB of a set control unit electrically connected to the source PCB for controlling the entire set device.

The display panel of the present disclosure may include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel may include a plurality of gate lines, a plurality of data lines and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of a moisture or oxygen into the emitting element layer. In addition, the emitting element layer on the array may include an inorganic light emitting layer, for example, a nano-sized material layer or a quantum dot.

The thin film transistor of the present disclosure may include one of an oxide thin film transistor, an amorphous silicon thin film transistor, and a low temperature polycrystalline silicon thin film transistor.

Features of various embodiments of the present disclosure may be partially or entirely coupled to or combined with each other. They may be linked and operated technically in various ways as those skilled in the art may sufficiently understand. The aspects may be carried out independently of or in association with each other in various combinations.

Hereinafter, a display device according to various example embodiments of the present disclosure where an influence on an oxide semiconductor layer of a thin film transistor of a driving element part is reduced by shielding a light emitted and transmitted from a subpixel and/or a light inputted from an exterior will be described in detail with reference to the accompanying drawings.

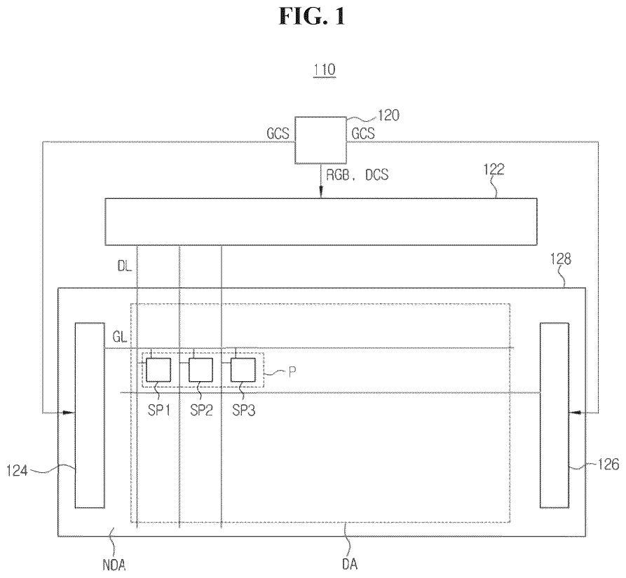

FIG. 1 is a view showing a display device according to a first embodiment of the present disclosure. Although the display device may be an organic light emitting diode (OLED) display device, it is not limited thereto. For example, the display device may be a micro light emitting diode (LED) display device or a mini light emitting diode (LED) display device.

In FIG. 1, a display device 110 according to a first embodiment of the present disclosure includes a timing controlling unit 120 (e.g., a circuit), a data driving unit 122 (e.g., a circuit), first and second gate driving units 124 and 126 (e.g., circuits) and a display panel 128.

The timing controlling unit 120 generates an image data RGB, a data control signal DCS and a gate control signal GCS using an image signal and a plurality of timing signals including a data enable signal, a horizontal synchronization signal, a vertical synchronization signal and a clock signal transmitted from an external system such as a graphic card or a television system. The timing controlling unit 120 transmits the image data RGB and the data control signal DCS to the data driving unit 122 and transmits the gate control signal GCS to the first and second gate driving units 124 and 126.

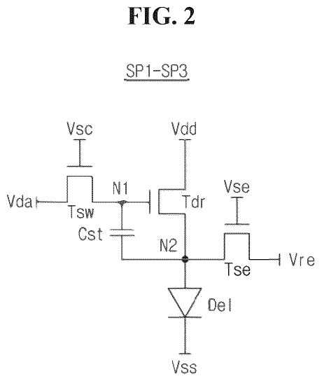

The data driving unit 122 generates a data signal (a data voltage) Vda (of FIG. 2) using the image data RGB and the data control signal DCS transmitted from the timing controlling unit 120 and transmits the data signal Vda to a data line DL of the display panel 128.

The first and second gate driving units 124 and 126 generate a gate signal (a gate voltage) Vsc and Vse (of FIG. 2) using the gate control signal GCS transmitted from the timing controlling unit 120 and applies the gate signal Vsc and Vse to a gate line GL of the display panel 128.

The first and second gate driving units 124 and 126 may have a gate in panel (GIP) type to be formed in a non-display area NDA of a substrate of the display panel 128 having the gate line GL, the data line DL and a pixel P.

Although the first and second gate driving units 124 and 126 are disposed in both side portions of the display panel 128 in the first embodiment of FIG. 1, one gate driving unit may be disposed in one side portion of the display panel 128 in another embodiment.

The display panel 128 includes a display area DA at a central portion thereof and a non-display area NDA surrounding the display area DA. The display panel 128 displays an image using the gate signal Vsc and Vse and the data signal Vda. For displaying an image, the display panel 128 includes a plurality of pixels P, a plurality of gate lines GL and a plurality of data lines DL in the display area DA.

Each of the plurality of pixels P includes a first subpixel SP1, a second subpixel SP2, and a third subpixel SP3, and the gate line GL and the data line DL cross each other to define the first, second and third subpixels SP1, SP2 and SP3. Each of the first, second and third subpixels SP1, SP2 and SP3 is connected to the gate line GL and the data line DL. For example, the first, second and third subpixels SP1, SP2 and SP3 may correspond to first, second and third colors, respectively, and the first, second and third colors may be red, green and blue colors, respectively.

Each of the first, second and third subpixels SP1, SP2 and SP3 may include a plurality of transistors such as a switching transistor Tsw (of FIG. 2), a driving transistor Tdr (of FIG. 2) and a sensing transistor Tse (of FIG. 2), a storage capacitor Cst (of FIG. 2) and a light emitting diode Del (of FIG. 2).

FIG. 2 is a circuit diagram showing a subpixel of a display device according to a first embodiment of the present disclosure.

In FIG. 2, each of the first, second and third subpixels SP1, SP2 and SP3 of the display panel 128 of the display device 110 according to a first embodiment of the present disclosure includes a switching transistor Tsw, a driving transistor Tdr, a sensing transistor Tse, a storage capacitor Cst, and a light emitting diode Del.

Although each of the first, second, and third subpixels SP1, SP2 and SP3 has a 3T1C structure having three transistors and one storage capacitor in the first embodiment of FIG. 2, each of the first, second and third subpixels SP1, SP2 and SP3 may have one of a 6T1C structure having six transistors and one storage capacitor, a 7T1C structure having seven transistors and one storage capacitor and a 8T1C structure having eight transistors and one storage capacitor in another embodiment.

Although the switching transistor Tsw, the driving transistor Tdr, and the sensing transistor Tse may have a negative type in the first embodiment of FIG. 2, at least one of the switching transistor Tsw, the driving transistor Tdr, and the sensing transistor Tse may have a positive type in another embodiment.

The switching transistor Tsw is switched according to a scan signal Vsc to transmit a data signal Vda to a first node N1.

A gate electrode of the switching transistor Tsw is connected to the gate line GL to receive the scan signal Vsc, a drain electrode of the switching transistor Tsw is connected to the data line DL to receive the data signal Vda, and a source electrode of the switching transistor Tsw is connected to the first node N1.

The driving transistor Tdr is switched according to a voltage of the first node N1 to transmit a high level signal (high level voltage) Vdd to a second node N2.

A gate electrode of the driving transistor Tdr is connected to the first node N1, a drain electrode of the driving transistor Tdr is connected to a high level power line to receive the high level signal Vdd, and a source electrode of the driving transistor Tdr is connected to the second node N2.

The sensing transistor Tse is switched according to a sensing signal (sensing voltage) Vse to transmit a reference signal (reference voltage) Vre to the second node N2 or transmit a voltage of the second node N2 to a reference line.

A gate electrode of the sensing transistor Tse is connected to the gate line GL to receive the sensing signal Vse, a drain electrode of the sensing transistor Tse is connected to the reference line to receive the reference signal Vre or transmit a voltage of the second node N2 to the reference line, and a source electrode of the sensing transistor Tse is connected to the second node N2.

The storage capacitor Cst keeps the data signal Vda supplied to the first node N1 for one frame and stores a threshold voltage of the driving transistor Tdr.

A first capacitor electrode of the storage capacitor Cst is connected to the first node N1, and a second capacitor electrode of the storage capacitor Cst is connected to the second node N2.

The light emitting diode Del emits a light of a luminance proportional to a current of the driving transistor Tdr.

An anode of the light emitting diode Del is connected to the second node N2, and a cathode of the light emitting diode Del is connected to a low level power line to receive a low level signal (low level voltage) Vss.

The source electrode of the switching transistor Tsw, the gate electrode of the driving transistor Tdr and the first capacitor electrode of the storage capacitor Cst constitute the first node N1, and the source electrode of the driving transistor Tdr, the source electrode of the sensing transistor Tse, the second capacitor electrode of the storage capacitor Cst and anode of the light emitting diode Del constitute the second node N2.

The light emitting diode Del may display an image having a luminance corresponding to the image data RGB according to a driving of subpixel circuits of the first, second and third subpixels SP1, SP2 and SP3.

A cross-sectional structure of each subpixel SP1, SP2 and SP3 of the display panel 128 of the display device 110 will be illustrated with reference to a drawing.

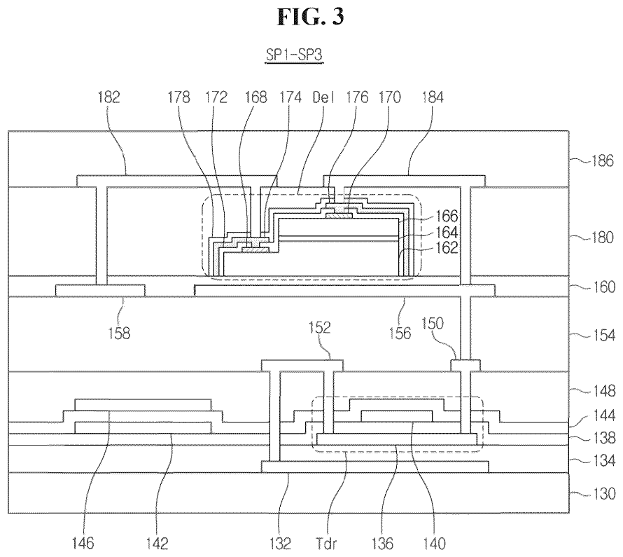

FIG. 3 is a cross-sectional view showing a subpixel of a display panel of a display device according to a first embodiment of the present disclosure.

In FIG. 3, a light shielding pattern 132 is disposed in each of the first, second and third subpixels SP1, SP2 and SP3 on a substrate 130, and a first buffer layer 134 is disposed on the light shielding pattern 132 over the entire substrate 130. In one embodiment, each subpixel may have its own light shielding pattern 132.

The light shielding pattern 132 may block a light incident from a lower portion of the substrate 130. For example, the light shielding pattern 132 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

The first buffer layer 134 may block a moisture or an oxygen permeating from an exterior. For example, the first buffer layer 134 may have a single layer or a multiple layer of an inorganic insulating material such as silicon oxide (SiO2) and silicon nitride (SiNx).

A semiconductor layer 136 is disposed on the first buffer layer 134 corresponding to the light shielding pattern 132, and a gate insulating layer 138 is disposed on the semiconductor layer 136 over the entire substrate 130. The light shielding pattern 132 overlaps the semiconductor layer 136 to shield the semiconductor layer 136 from external light.

The semiconductor layer 136 includes a channel region not doped with an impurity at a central portion thereof and source and drain regions doped with an impurity at both side portions of the channel region. For example, the semiconductor layer 136 may include a polycrystalline semiconductor material such as polycrystalline silicon or an oxide semiconductor material such as indium gallium zinc oxide (IGZO), zinc oxide (ZnO), tin oxide (SnO2), copper oxide (Cu2O), nickel oxide (NiO), indium tin zinc oxide (ITZO) and indium aluminum zinc oxide (IAZO).

For example, the gate insulating layer 138 may have a single layer or a multiple layer of an inorganic insulating material such as silicon oxide (SiO2) and silicon nitride (SiNx).

A gate electrode 140 is disposed on the gate insulating layer 138 corresponding to the channel region of the semiconductor layer 136, a first capacitor electrode 142 separated from the gate electrode 140 is disposed on the gate insulating layer 138, and a first interlayer insulating layer 144 is disposed on the gate electrode 140 and the first capacitor electrode 142. The gate electrode 140 may overlap the channel region of the semiconductor layer 136.

The gate electrode 140 and the first capacitor electrode 142 may be disposed on the same layer (e.g., the gate insulating layer 138) and include a same material as each other. For example, the gate electrode 140 and the first capacitor electrode 142 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

For example, the first interlayer insulating layer 144 may have a single layer or a multiple layer of an inorganic insulating material such as silicon oxide (SiO2) and silicon nitride (SiNx).

A second capacitor electrode 146 is disposed on the first interlayer insulating layer 144 and overlaps the first capacitor electrode 142, and a second interlayer insulating layer 148 is disposed on the second capacitor electrode 146 over the entire substrate 130.

For example, the second capacitor electrode 146 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

For example, the second interlayer insulating layer 148 may have a single layer or a multiple layer of an inorganic insulating material such as silicon oxide (SiO2) and silicon nitride (SiNx).

The first capacitor electrode 142, the first interlayer insulating layer 144, and the second capacitor electrode 146 may collectively constitute the storage capacitor Cst.

A source electrode 150 and a drain electrode 152 spaced apart from each other are disposed on the second interlayer insulating layer 148, and a first planarizing layer 154 is disposed on the source electrode 150 and the drain electrode 152 over the entire substrate 130.

The source electrode 150 and the drain electrode 152 are connected to the source region and the drain region, respectively, of the semiconductor layer 136 through contact holes in the second interlayer insulating layer 148, the first interlayer insulating layer 144 and the gate insulating layer 138, and the drain electrode 152 is connected to the light shielding pattern 132 through a contact hole in the second interlayer insulating layer 148, the first interlayer insulating layer 144, the gate insulating layer 138 and the first buffer layer 134.

The source electrode 150 and the drain electrode 152 may have the same layer and the same material as each other. For example, the source electrode 150 and the drain electrode 152 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

For example, the first planarizing layer 154 may have a single layer or a multiple layer of an organic insulating material such as photoacryl and benzocyclobutene (BCB).

The semiconductor layer 136, the gate electrode 140, the source electrode 150 and the drain electrode 152 may constitute the driving transistor Tdr.

A connecting electrode 156 is disposed on the first planarizing layer 154 corresponding to the source electrode 150, a power line 158 that is spaced apart from the connecting electrode 156 is disposed on the first planarizing layer 154, and an adhesive layer 160 is disposed on the connecting electrode 156 and the power line 158 over the entire substrate 130.

The connecting electrode 156 is connected to the source electrode 150 through a contact hole in the first planarizing layer 154, and the connecting electrode 156 and the power line 158 may have the same layer and the same material as each other.

For example, the connecting electrode 156 and the power line 158 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

For example, the power line 158 may supply the low level signal Vss.

A first semiconductor layer 162 is disposed on the adhesive layer 160 and overlaps the connecting electrode 156, an active layer 164, a second semiconductor layer 166 and a second electrode 170 are sequentially disposed on a first side portion of the first semiconductor layer 162, and a first electrode 168 is disposed on a second side portion of the first semiconductor layer 162.

The first semiconductor layer 162 supplies an electron to the active layer 164, the second semiconductor layer 166 supplies a hole to the active layer 164, and the active layer 164 generates a light using an electron and a hole.

For example, the first semiconductor layer 162 may include negative type gallium nitride (n-GaN), the second semiconductor layer 166 may include positive type gallium nitride (p-GaN), and the active layer 164 may include multi quantum well (MQW).

For example, the first electrode 168 may be a cathode, and the second electrode 170 may be an anode.

The first semiconductor layer 162, the active layer 164, the second semiconductor layer 166, the first electrode 168 and the second electrode 170 may constitute the light emitting diode Del (or the light emitting diode chip). In addition, the light emitting diode Del (or the light emitting diode chip) according to a first embodiment of the present disclosure further includes a first chip insulating layer 172, a first test electrode 174, a second test electrode 176 and a second chip insulating layer 178.

The first chip insulating layer 172 is disposed on the first and second electrodes 168 and 170 over the entire light emitting diode Del, the first and second test electrodes 174 and 176 spaced apart from each other are disposed on the first chip insulating layer 172, and the second chip insulating layer 178 is disposed on the first and second test electrodes 174 and 176 over the entire light emitting diode Del. The first chip insulating layer 172 may be in direct contact with the first electrode 168 and the second electrode 170. The second chip insulating layer 178 may be in direct contact with the first test electrode 174 and the second test electrode 176.

The first chip insulating layer 172 may contact (e.g., direct contact) a side surface of the first semiconductor layer 162, a side surface of the active layer 164, and side and top surfaces of the second semiconductor layer 166, the first and second test electrodes 174 and 176 may contact side and top surfaces of the first chip insulating layer 172, and the second chip insulating layer 178 may contact side and top surfaces of the first and second test electrodes 174 and 176.

For example, the first and second chip insulating layers 172 and 178 may have a single layer or a multiple layer of an inorganic insulating material such as silicon oxide (SiO2) and silicon nitride (SiNx).

The first test electrode 174 is connected to the first electrode 168 through a contact hole in the first chip insulating layer 172, and the second test electrode 176 is connected to the second electrode 170 through a contact hole in the first chip insulating layer 172.

For example, the first and second test electrodes 174 and 176 may include a transparent conductive material such as indium tin oxide (ITO) and indium zinc oxide (IZO).

As shown in FIG. 3, an end of the first test electrode 174, an end of the second test electrode 176, an end of the first chip insulating layer 172, and a bottom surface of the first semiconductor layer 162 are planar with each other. As a result, the end of the first test electrode 174, the end of the second test electrode 176, the end of the first chip insulating layer 172, and the bottom surface of the first semiconductor layer 162 are in direct contact with the adhesive layer 160. Furthermore, the end of the first test electrode 174 is between a first end of the first chip insulating layer 172 and a first end of the second chip insulating layer 178 at a first side (e.g., a left side) of the first semiconductor layer 162. Additionally, the end of the second test electrode 176 is between a second end of the first chip insulating layer 172 and a second end of the second chip insulating layer 178 at a second side (e.g., a right side) of the first semiconductor layer.

A second planarizing layer 180 is disposed on the second chip insulating layer 178 over the entire substrate 130, and first and second connecting lines 182 and 184 spaced apart from each other are disposed on the second planarizing layer 180 corresponding to the light emitting diode Del.

For example, the second planarizing layer 180 may have a single layer or a multiple layer of an organic insulating material such as photoacryl and benzocyclobutene (BCB).

The first connecting line 182 is connected to the power line 158 through a contact hole in the adhesive layer 160 and a contact hole in the second planarizing layer 180 and is connected to the first test electrode 174 through a contact hole in the second planarizing layer 180 and a contact hole in the second chip insulating layer 178.

The second connecting line 184 is connected to the connecting electrode 156 through a contact hole in the adhesive layer 160 and a contact hole in the second planarizing layer 180 and is connected to the second test electrode 176 through a contact hole in the second planarizing layer 180 and a contact hole in the second chip insulating layer 178.

For example, the first and second connecting lines 182 and 184 may include a metallic material such as one of molybdenum (Mo), aluminum (Al), chromium (Cr), gold (Au), titanium (Ti), nickel (Ni), neodymium (Nd) and copper (Cu) or a transparent conductive material such as indium tin oxide (ITO) and indium zinc oxide (IZO).

An encapsulating layer 186 is disposed on the first and second connecting lines 182 and 184 over the entire substrate 130.

The encapsulating layer 186 prevents or at least reduces a permeation of a particle such as an oxygen or a moisture.

For example, the encapsulating layer 186 may have a single layer or a multiple layer of an inorganic insulating material such as silicon oxide (SiO2) and silicon nitride (SiNx).

Although the light emitting diode Del exemplarily has a horizontal type in the first embodiment, the light emitting diode Del may have a vertical type in another embodiment.

The light emitting diode Del of the display device 110 may be formed on the growth substrate and may be attached to the substrate 130 through a lighting test.

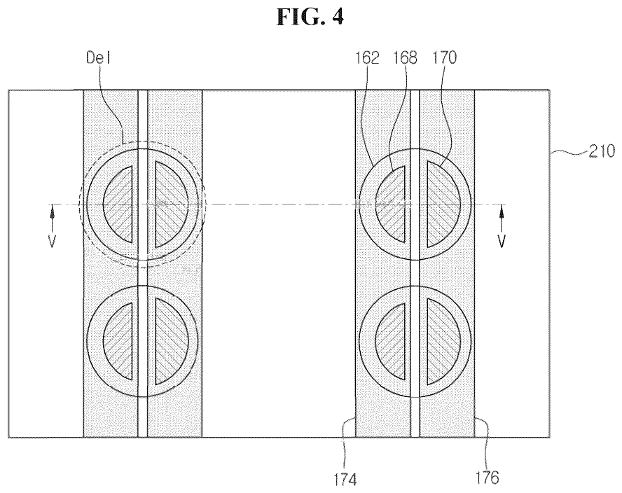

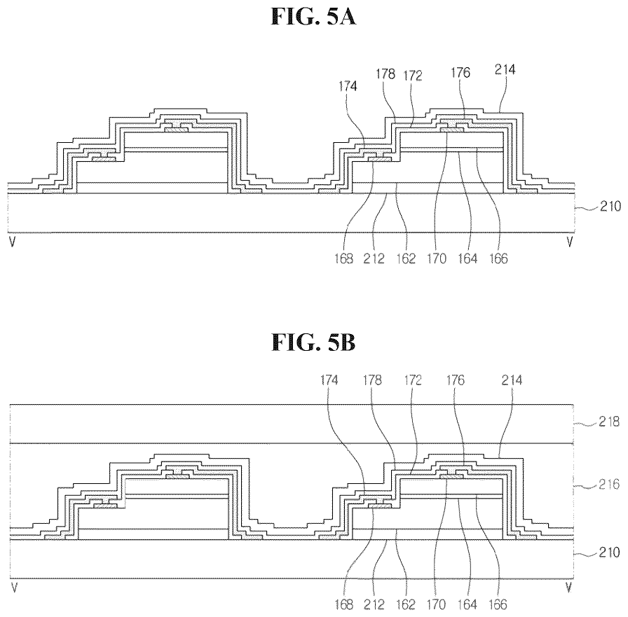

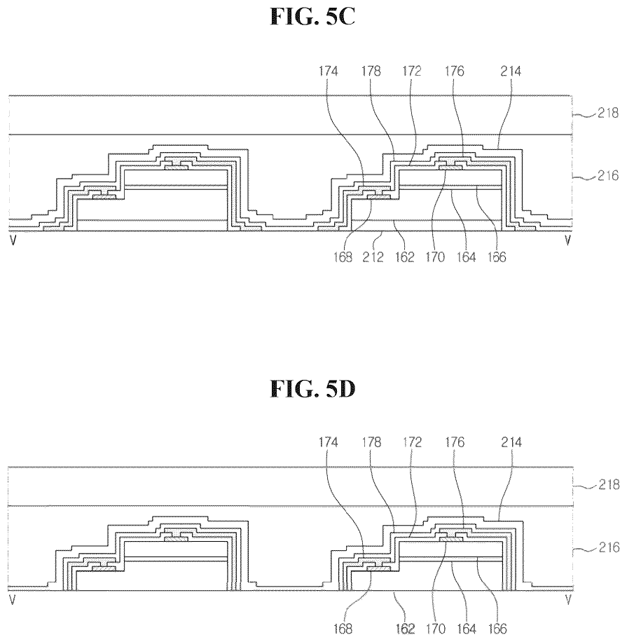

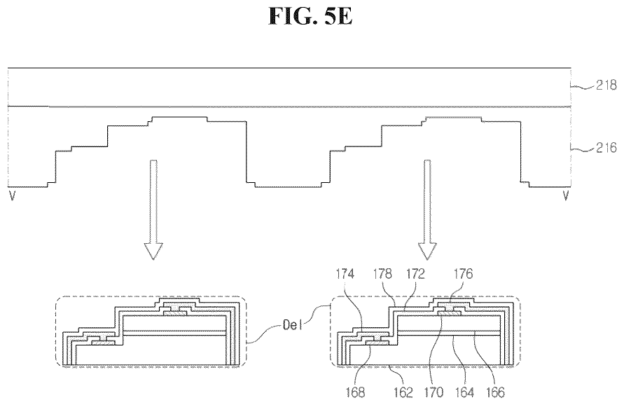

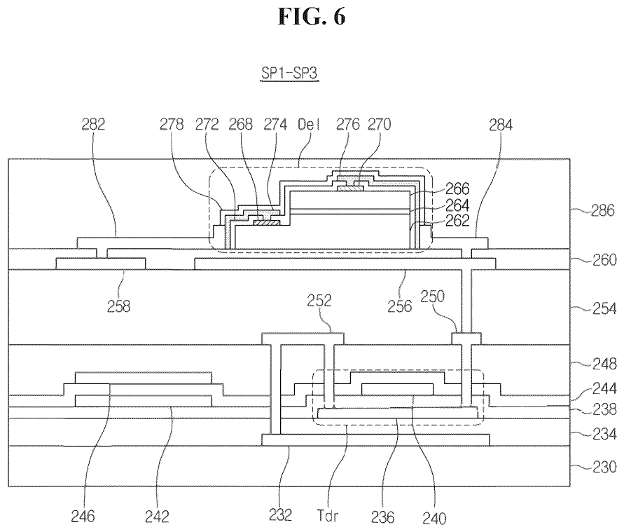

FIG. 4 is a view showing a light emitting diode attached to a display device according to a first embodiment of the present disclosure, and FIGS. 5A to 5E are views showing a method of fabricating a light emitting diode attached to a display device according to a first embodiment of the present disclosure. FIGS. 5A to 5E correspond to a line V-V of FIG. 4.

In FIG. 4, a plurality of light emitting diodes Del spaced apart from each other are disposed on a growth substrate 210, and the first and second test electrodes 174 and 176 are disposed on the plurality of light emitting diodes Del.

The plurality of light emitting diodes Del are disposed in a matrix shape along horizontal and vertical directions, and each of the plurality of light emitting diodes Del includes the first semiconductor layer 162, the first electrode 168 and the second electrode 170.

Each of the first and second test electrodes 174 and 176 has a bar shape and is disposed along the vertical direction (e.g., Y-direction). The first and second test electrodes 174 and 176 are disposed on the first and second electrodes 168 and 170, respectively.

The first test electrode 174 is connected to the first electrodes 168 of the plurality of light emitting diodes Del disposed along the vertical direction. The second test electrode 176 is connected to the second electrodes 170 of the plurality of light emitting diodes Del disposed along the vertical direction. As a result, the plurality of light emitting diodes Del disposed in one column along the vertical direction are connected to one pair of the first and second test electrodes 174 and 176 in parallel.

The lighting of the plurality of light emitting diodes Del connected to the first and second test electrodes 174 and 176 is detected in a state that a high level signal Vdd and a low level signal Vss are applied to the first and second test electrodes 174 and 176, respectively. As a result, a normal operation or an abnormal operation of each of the plurality of light emitting diodes Del connected to the first and second test electrodes 174 and 176 may be judged before the plurality of light emitting diodes Del are attached to the substrate 130 of the display panel 128.

In FIG. 5A, an etch stopping layer 212, the first semiconductor layer 162, the active layer 164 and the second semiconductor layer 166 are sequentially formed on the growth substrate 210 by sequentially depositing and patterning an etch stopping material, a first semiconductor material, an active material and a second semiconductor material on the growth substrate 210.

For example, the growth substrate 210 may include gallium arsenide (GaAs), and the etch stopping layer 212 may include indium gallium phosphide (InGaP). The first semiconductor layer 162 may include negative type gallium nitride (n-GaN), the second semiconductor layer 166 may include positive type gallium nitride (p-GaN), and the active layer 164 may include multi quantum well (MQW).

The second semiconductor layer 166 is disposed on a first side portion of the first semiconductor layer 162, and the second semiconductor layer 166 and the active layer 164 on a second side portion of the first semiconductor layer 162 and a portion of the first semiconductor layer 162 in the second side portion are removed such that the first semiconductor layer 162 is exposed.

Next, the first electrode 168 is formed on the second side portion of the first semiconductor layer 162 and the second electrode 170 is formed on the second semiconductor layer 166 over the first side portion of the first semiconductor layer 162 by depositing and patterning a metallic material on the second semiconductor layer 166 over the first side portion of the first semiconductor layer 162 and the second side portion of the first semiconductor layer 162.

For example, the first and second electrodes 168 and 170 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

Next, the first chip insulating layer 172 is formed on the first and second electrodes 168 and 170 by depositing and patterning an inorganic insulating material on the first and second electrodes 168 and 170.

For example, the first chip insulating layer 172 may have a single layer or a multiple layer of an inorganic insulating material such as silicon oxide (SiO2) and silicon nitride (SiNx).

Next, the first and second test electrodes 174 and 176 spaced apart from each other are formed on the first chip insulating layer 172 by depositing and patterning a transparent conductive material on the first chip insulating layer 172.

The first test electrode 174 is connected to the first electrode 168 through a contact hole in the first chip insulating layer 172, and the second test electrode 176 is connected to the second electrode 170 through a contact hole in the first chip insulating layer 172.

For example, the first and second test electrodes 174 and 176 may include a transparent conductive material such as indium tin oxide (ITO) and indium zinc oxide (IZO).

Next, the second chip insulating layer 178 is formed on the first and second test electrodes 174 and 176 by depositing and patterning an inorganic insulating material on the first and second test electrodes 174 and 176.

For example, the second chip insulating layer 178 may have a single layer or a multiple layer of an inorganic insulating material such as silicon oxide (SiO2) and silicon nitride (SiNx).

Next, a sacrificing layer 214 is formed on the second chip insulating layer 178 over the entire growth substrate 210 by depositing a sacrificing material on the second chip insulating layer 178.

For example, the sacrificing layer 214 may have a single layer or a multiple layer of an inorganic insulating material such as silicon oxide (SiO2) and silicon nitride (SiNx) or may include a metallic material such as aluminum (Al) and titanium (Ti) or a transparent conductive material such as indium tin oxide (ITO) and zinc oxide (ZnO).

In FIG. 5B, a chip planarizing layer 216 is formed on the sacrificing layer 214 over the entire growth substrate 210 by depositing an organic insulating material on the sacrificing layer 214.

For example, the chip planarizing layer 216 may include an organic insulating material such as photoacryl and benzocyclobutene (BCB).

Next, a transfer substrate 218 is attached to the chip planarizing layer 216.

For example, the transfer substrate 218 may include a glass or an organic insulating material.

In FIG. 5C, the growth substrate 210 is removed from the etch stopping layer 212 through a chemical lift off (CLO) or a chemical mechanical polishing (CMP).

As a result, bottom surfaces of the first and second test electrodes 174 and 176 at both sides of the etch stopping layer 212 are exposed.

Next, a lighting test that the plurality of light emitting diodes Del connected to the first and second test electrodes 174 and 176 are simultaneously turned on by applying the high level signal Vdd and the low level signal Vss to the first and second test electrodes 174 and 176, respectively, is performed, and the normal operation or the abnormal operation of the plurality of light emitting diodes Del is simultaneously judged.

In FIG. 5D, the etch stopping layer 212 is removed from the first semiconductor layer 162 through a chemical mechanical polishing (CMP).

Here, the first chip insulating layer 172, the first and second test electrodes 174 and 176 and the second chip insulating layer 178 on the growth substrate 210 extending from a side surface of the etch stopping layer 212 outwardly are removed together with the etch stopping layer 212 such that a bottom surface of the sacrificing layer 214 outside the side surface of the second chip insulating layer 178 may be exposed.

Since the etch stopping layer 212 is removed through a chemical mechanical polishing (CMP), deterioration such as a burr of the first chip insulating layer 172 generated during a dry etch due to an etch rate difference between the etch stopping layer 212 and the first chip insulating layer 172 is prevented.

In FIG. 5E, the plurality of light emitting diodes Del each including the first semiconductor layer 162, the active layer 164, the second semiconductor layer 166, the first and second electrodes 168 and 170, the first and second chip insulating layers 172 and 178 and the first and second test electrodes 174 and 176 are detached from the chip planarizing layer 216 by removing the sacrificing layer 214 through a wet etch or a laser lift off.

Next, the plurality of light emitting diodes Del detached from the chip planarizing layer 216 are attached to the adhesive layer 160 of the substrate 130 in the first, second and third subpixels SP1, SP2 and SP3.

Next, the display panel 128 is completed by forming the second planarizing layer 180, the first and second connecting lines 182 and 184 and the encapsulating layer 186 on the plurality of light emitting diodes Del.

In the display device 110 and the method of fabricating the display device 110 according to a first embodiment of the present disclosure, the lighting test is performed after the first and second test electrodes 174 and 176 are formed on the plurality of light emitting diodes Del of the growth substrate 210, and the light emitting diode Del judged as a normal operation is selectively attached to the display panel 128. As a result, deterioration is reduced, the production yield increases, and the fabrication cost is reduced.

In another embodiment, the first and second connecting lines may be connected to the side surfaces of the first and second test electrodes.

FIG. 6 is a cross-sectional view showing a subpixel of a display panel of a display device according to a second embodiment of the present disclosure. Illustration on parts the same as those of the first embodiment may be omitted.

In FIG. 6, a light shielding pattern 232 is disposed in each of first, second and third subpixels SP1, SP2 and SP3 on a substrate 230, and a first buffer layer 234 is disposed on the light shielding pattern 232 over the entire substrate 230.

A semiconductor layer 236 is disposed on the first buffer layer 234 corresponding to the light shielding pattern 232, and a gate insulating layer 238 is disposed on the semiconductor layer 236 over the entire substrate 230.

The semiconductor layer 236 includes a channel region not doped with an impurity at a central portion thereof and source and drain regions doped with an impurity at both side portions of the channel region.

A gate electrode 240 is disposed on the gate insulating layer 238 corresponding to the channel region of the semiconductor layer 236, a first capacitor electrode 242 separated from the gate electrode 240 is disposed on the gate insulating layer 238, and the a first interlayer insulating layer 244 is disposed on the gate electrode 240 and the first capacitor electrode 242.

A second capacitor electrode 246 is disposed on the first interlayer insulating layer 244 corresponding to the first capacitor electrode 242, and a second interlayer insulating layer 248 is disposed on the second capacitor electrode 246 over the entire substrate 230.

The first capacitor electrode 242, the first interlayer insulating layer 244 and the second capacitor electrode 246 may constitute the storage capacitor Cst.

A source electrode 250 and a drain electrode 252 spaced apart from each other are disposed on the second interlayer insulating layer 248, and a first planarizing layer 254 is disposed on the source electrode 250 and the drain electrode 252 over the entire substrate 230.

The source electrode 250 and the drain electrode 252 are connected to the source region and the drain region, respectively, of the semiconductor layer 236 through contact holes in the second interlayer insulating layer 248, the first interlayer insulating layer 244 and the gate insulating layer 238, and the drain electrode 252 is connected to the light shielding pattern 232 through contact holes in the second interlayer insulating layer 248, the first interlayer insulating layer 244, the gate insulating layer 238 and the first buffer layer 234.

The semiconductor layer 236, the gate electrode 240, the source electrode 250 and the drain electrode 252 may constitute the driving transistor Tdr.

A connecting electrode 256 is disposed on the first planarizing layer 254 corresponding to the source electrode 250, a power line 258 spaced apart from the connecting electrode 256 is disposed on the first planarizing layer 254, and an adhesive layer 260 is disposed on the connecting electrode 256 and the power line 258 over the entire substrate 230.

The connecting electrode 256 is connected to the source electrode 250 through a contact hole in the first planarizing layer 254.

A first semiconductor layer 262 is disposed on the adhesive layer 260 corresponding to the connecting electrode 256, an active layer 264, a second semiconductor layer 266 and a second electrode 270 are sequentially disposed on a first side portion of the first semiconductor layer 262, and a first electrode 268 is disposed on a second side portion of the first semiconductor layer 262.

The first semiconductor layer 262, the active layer 264, the second semiconductor layer 266, the first electrode 268 and the second electrode 270 may constitute the light emitting diode Del (or the light emitting diode chip).

A first chip insulating layer 272 is disposed on the first and second electrodes 268 and 270 over the entire light emitting diode Del, first and second test electrodes 274 and 276 spaced apart from each other are disposed on the first chip insulating layer 272, and a second chip insulating layer 278 is disposed on the first and second test electrodes 274 and 276 over the entire light emitting diode Del.

The first chip insulating layer 272 may be disposed on a side surface and a portion of a top surface of the first semiconductor layer 262, a side surface of the active layer 264 and side and a side surface and a portion of a top surface of the second semiconductor layer 266, and the first and second test electrodes 274 and 276 may be disposed on side and top surfaces of the first chip insulating layer 272.

Further, the second chip insulating layer 278 may be disposed on a top surface and portions of side surfaces of the first and second test electrodes 274 and 276, and the other portions of the side surfaces of the first and second test electrodes 274 and 276 may be exposed to an exterior.

The first test electrode 274 is connected to the first electrode 268 through a contact hole in the first chip insulating layer 272, and the second test electrode 276 is connected to the second electrode 270 through a contact hole in the first chip insulating layer 272.

As shown in FIG. 6, an end of the first test electrode 274, an end of the second test electrode 276, an end of the first chip insulating layer 272, and a bottom surface of the first semiconductor layer 262 are planar with each other. As a result, the end of the first test electrode 274, the end of the second test electrode 276, the end of the first chip insulating layer 272, and the bottom surface of the first semiconductor layer 262 are in direct contact with the adhesive layer 260. Furthermore, a first end of the first chip insulating layer 272 (e.g., a left end) is between a first side of the first semiconductor layer 262 (e.g., a left side) and an end of the first test electrode 274 and a second end of the first chip insulating layer 272 (e.g., a right end) is between a second side of the first semiconductor layer 262 (e.g., a right side) and an end of the second test electrode 276.

First and second connecting lines 282 and 284 spaced apart from each other are disposed on the adhesive layer 260.

The first connecting line 282 is connected to the power line 258 through a contact hole in the adhesive layer 260 and is connected to the other portion of the side surface of the first test electrode 274 exposed through the second chip insulating layer 278.

The second connecting line 284 is connected to the connecting electrode 256 through a contact hole in the adhesive layer 260 and is connected to the other portion of the side surface of the second test electrode 276 exposed through the second chip insulating layer 278.

For example, the first and second connecting lines 282 and 284 may include a metallic material such as one of molybdenum (Mo), aluminum (Al), chromium (Cr), gold (Au), titanium (Ti), nickel (Ni), neodymium (Nd) and copper (Cu) or a transparent conductive material such as indium tin oxide (ITO) and indium zinc oxide (IZO).

An encapsulating layer 286 is disposed on the first and second connecting lines 282 and 284 over the entire substrate 230.

Although the light emitting diode Del exemplarily has a horizontal type in the second embodiment, the light emitting diode Del may have a vertical type in another embodiment.

In the display device and the method of fabricating the display device according to a second embodiment of the present disclosure, the lighting test is performed after the first and second test electrodes 274 and 276 are formed on the plurality of light emitting diodes Del of the growth substrate 210, and the light emitting diode Del judged as a normal operation is selectively attached to the display panel. As a result, deterioration is reduced, the production yield increases, and the fabrication cost is reduced.

Further, the first and second connecting lines 282 and 284 are disposed at both sides, respectively, of the light emitting diode Del and are connected to the side surfaces of the first and second test electrodes, respectively. As a result, an emission region of a light emitted from the light emitting diode Del expands to improve a light efficiency.

Consequently, in a display device and a method of fabricating the display device according to first and second embodiments of the present disclosure, deterioration is reduced, a production yield increases, and a fabrication process is optimized by forming a test electrode on a light emitting diode of a growth substrate and performing a lighting test.

Further, a fabrication cost is reduced by forming a test electrode on a light emitting diode of a growth substrate and attaching the light emitting diode of a normal operation to a display panel after a lighting test.

It will be apparent to those skilled in the art that various modifications and variation may be made in the present disclosure without departing from the scope of the disclosure. Thus, it is intended that the present disclosure cover the modifications and variations of this disclosure provided they come within the scope of the appended claims and their equivalents.

What is claimed is:

1. A light emitting diode, comprising:
a first semiconductor layer;
an active layer on a first portion of the first semiconductor layer;
a second semiconductor layer on the active layer;
a first electrode on a second portion of the first semiconductor layer that is spaced apart from the first portion of the first semiconductor layer;
a second electrode on the second semiconductor layer;
a first chip insulating layer on the first electrode and the second electrode;
a first test electrode and a second test electrode on the first chip insulating layer, the first test electrode connected to the first electrode and the second test electrode connected to the second electrode; and
a second chip insulating layer on the first test electrode and the second test electrode.

2. The light emitting diode of claim 1, wherein the first chip insulating layer contacts a side surface of the first semiconductor layer, a side surface of the active layer, a side surface of the second semiconductor layer, and a top surface of the second semiconductor layer,
wherein each of the first test electrode and the second test electrode contacts a side surface and a top surface of the first chip insulating layer, and
wherein the second chip insulating layer contacts a side surface and a top surface of each of the first test electrode and the second test electrode.

3. The light emitting diode of claim 1, wherein an end of the first test electrode is between a first end of the first chip insulating layer and a first end of the second chip insulating layer at a first side of the first semiconductor layer and an end of the second test electrode is between a second end of the first chip insulating layer and a second end of the second chip insulating layer at a second side of the first semiconductor layer.

4. The light emitting diode of claim 1, wherein a first end of the first chip insulating layer is between a first side of the first semiconductor layer and an end of the first test electrode and a second end of the first chip insulating layer is between a second side of the first semiconductor layer and an end of the second test electrode.

5. A display device, comprising:
a gate line and a data line;
a transistor connected to the gate line and the data line;
a planarizing layer on the transistor;
a connecting electrode on the planarizing layer, the connecting electrode connected to the transistor;
an adhesive layer on the connecting electrode;
a light emitting diode on the adhesive layer; and
a first connecting line on the adhesive layer, the first connecting line on a side surface of the light emitting diode at a first side of the light emitting diode; and
a second connecting line on the adhesive layer, the second connecting line connected to the connecting electrode and on the side surface of the light emitting diode at a second side of the light emitting diode.

6. The display device of claim 5, wherein the light emitting diode comprises:
a first semiconductor layer;
an active layer on a first portion of the first semiconductor layer;
a second semiconductor layer on the active layer;
a first electrode on a second portion of the first semiconductor layer that is spaced apart from the first portion of the first semiconductor layer;
a second electrode on the second semiconductor layer;
a first chip insulating layer on the first electrode and the second electrode;
a first test electrode and a second test electrode on the first chip insulating layer, the first test electrode connected to the first electrode and the second test electrode connected to the second electrode; and
a second chip insulating layer on the first test electrode and the second test electrode.

7. The display device of claim 6, wherein the first connecting line is connected to a portion of a side surface of the first test electrode that is exposed through the second chip insulating layer and a power line, and the second connecting line is connected to the connecting electrode through a contact hole in the adhesive layer and is connected to a portion of a side surface of the second test electrode exposed through the second chip insulating layer.

8. A method of fabricating a light emitting diode, comprising:
sequentially forming an etch stopping layer, a first semiconductor layer, an active layer and a second semiconductor layer on a growth substrate;
forming a first electrode on the first semiconductor layer and a second electrode on the second semiconductor layer;
forming a first test electrode on the first electrode such that the first test electrode is connected to the first electrode and a second test electrode on the second electrode such that the second test electrode is connected to the second electrode;
forming a sacrificing layer on the first test electrode and the second test electrode;
attaching a transfer substrate on the sacrificing layer;
removing the growth substrate from the etch stopping layer;
performing a lighting test by applying a high level signal to the first test electrode and a low level signal to the second test electrode;
removing the etch stopping layer from the first semiconductor layer; and
detaching a light emitting diode including the first semiconductor layer, the active layer, the second semiconductor layer, the first electrode, and the second electrode from the transfer substrate by removing the sacrificing layer.

9. The method of claim 8, wherein removing the growth substrate from the etch stopping layer comprises one of a chemical lift off or a chemical mechanical polishing to remove the growth substrate,
wherein removing the etch stopping layer from the first semiconductor layer comprises a chemical mechanical polishing to remove the etch stopping layer, and
wherein detaching the light emitting diode from the transfer substrate comprises one of a wet etch or a laser lift off to detach the light emitting diode from the transfer substrate.

10. The method of claim 8, further comprising:
forming a first chip insulating layer between the first electrode and the second electrode and the first test electrode and the second test electrode; and
forming a second chip insulating layer between the first test electrode and the second test electrode and the sacrificing layer,
wherein the first chip insulating layer contacts a side surface and a portion of a top surface of the first semiconductor layer, a side surface of the active layer, and a side surface and a portion of a top surface of the second semiconductor layer,
wherein each of the first test electrode and the second test electrode contacts a side surface and a top surface of the first chip insulating layer, and
wherein the second chip insulating layer contacts side surfaces and top surfaces of the first test electrode and the second test electrode.

11. The method of claim 8, wherein bottom surfaces of the first test electrode and the second test electrode at both sides of the etch stopping layer are exposed after removing the growth substrate from the etch stopping layer, and the high level signal is applied to the bottom surface of the first test electrode and the low level signal is applied to the bottom surface of the second test electrode while performing the lighting test.

12. A display device, comprising:
a substrate;
a transistor on the substrate;
a first planarizing layer on the transistor; and
a light-emitting element that is electrically connected to the transistor, the light-emitting element comprising:
a first semiconductor layer;
an active layer on a first portion of the first semiconductor layer;
a second semiconductor layer on the active layer;
a first electrode on a second portion of the first semiconductor layer that is spaced apart from the first portion of the first semiconductor layer;
a second electrode on the second semiconductor layer;
a first chip insulating layer on the first electrode and the second electrode;
a first test electrode and a second test electrode on the first chip insulating layer, the first test electrode connected to the first electrode and the second test electrode connected to the second electrode; and
a second chip insulating layer on the first test electrode and the second test electrode,
wherein an end of the first test electrode, an end of the second test electrode, at least one end of the first chip insulating layer, and a bottom surface of the first semiconductor layer are planar with each other.

13. The display device of claim 12, wherein the end of the first test electrode is between a first end of the first chip insulating layer and a first end of the second chip insulating layer at a first side of the first semiconductor layer and the end of the second test electrode is between a second end of the first chip insulating layer and a second end of the second chip insulating layer at a second side of the first semiconductor layer.

14. The display device of claim 13, wherein the first end and the second end of the second chip insulating layer are planar with the end of the first test electrode, the end of the second test electrode, the first end and the second end of the first chip insulating layer, and the bottom surface of the first semiconductor layer.

15. The display device of claim 12, wherein a first end of the first chip insulating layer is between a first side of the first semiconductor layer and the end of the first test electrode and a second end of the first chip insulating layer is between a second side of the first semiconductor layer and the end of the second test electrode.

16. The display device of claim 12, further comprising:
a connecting electrode on the first planarizing layer, the connecting electrode connected to the transistor and the light-emitting element; and
an adhesive layer on the connecting electrode,
wherein the end of the first test electrode, the end of the second test electrode, the at least one end of the first chip insulating layer, and the bottom surface of the first semiconductor layer are in direct contact with the adhesive layer.

17. The display device of claim 16, further comprising:
a first connecting line on the adhesive layer, the first connecting line on a side surface of the light-emitting element at a first side of the light-emitting element; and
a second connecting line on the adhesive layer, the second connecting line connected to the connecting electrode and on the side surface of the light-emitting element at a second side of the light-emitting element.

18. The display device of claim 17, wherein the first connecting line is connected to a portion of a side surface of the first test electrode that is exposed through the second chip insulating layer, and the second connecting line is connected to the connecting electrode through a contact hole in the adhesive layer and is connected to a portion of a side surface of the second test electrode exposed through the second chip insulating layer.

19. The display device of claim 16, further comprising:
a power line on the first planarizing layer;
a second planarizing layer on the light-emitting element; and
a first connecting line on the second planarizing layer, the first connecting line connected to the power line and the first test electrode; and
a second connecting line on the second planarizing layer, the second connecting line connected to the second test electrode and the connecting electrode.

20. The display device of claim 12, wherein the light-emitting element is a micro light emitting diode.
